(19) United States
(12) Patent Application Publication
(10) Pub. No.: US 2014/0098507 A1
(43) Pub. Date: Apr. 10, 2014

(54) PRINTED CIRCUIT BOARD, SEMICONDUCTOR PACKAGE USING THE SAME, AND METHOD FOR MANUFACTURING THE PRINTED CIRCUIT BOARD AND THE SEMICONDUCTOR PACKAGE

(71) Applicant: SAMSUNG ELECTRO-MECHANICS CO., LTD., Gyeonggi-do (KR)

(72) Inventors: Young Soon Kim, Chungcheongnam-do (KR); Jun Han Kim, Chungcheongnam-do (KR)

(73) Assignee: SAMSUNG ELECTRO-MECHANICS CO., LTD., Gyeonggi-do (KR)

(21) Appl. No.: 13/826,296

(22) Filed: Mar. 14, 2013

(30) Foreign Application Priority Data
Oct. 5, 2012 (KR) 10-2012-0110678

(51) Int. Cl. H01L 23/00; H05K 3/10; H05K 1/18; H05K 1/03; H05K 3/40

(52) U.S. Cl. CPC H01L 24/17; H01L 24/81; H05K 1/0313; H05K 3/4007; H05K 1/181; H05K 3/10
USPC 361/783; 438/125; 174/261; 174/255; 174/258; 29/848

(57) ABSTRACT

The present invention relates to a printed circuit board, a semiconductor package using the same, and a method for manufacturing the printed circuit board and the semiconductor package. The method for manufacturing a semiconductor package in accordance with the present invention includes: forming a circuit of a predetermined pattern on a PCB substrate; applying a first insulating material on the substrate; removing the first insulating material in the remaining portion except a predetermined portion by exposing and developing the substrate; forming a solder bump in the circuit portion exposed; molding a certain region of an upper surface portion of the PCB substrate including the solder bump by filling a second insulating material on the PCB substrate including the circuit portion; mounting a semiconductor chip on the PCB substrate; and completing one package in which the semiconductor chip and the PCB substrate are integrated.

### CROSS-REFERENCE TO RELATED APPLICATIONS

Claim and incorporate by reference domestic priority application and foreign priority application as follows:

### Cross Reference To Related Application

This application claims the benefit under 35 U.S.C. Section 119 of Korean Patent Application Serial No. 10-2012-0110678, entitled filed Oct. 5, 2012, which is hereby incorporated by reference in its entirety into this application.

### BACKGROUND OF THE INVENTION

1. Field of the Invention

The present invention relates to a printed circuit board, a semiconductor package using the same, and a method for manufacturing the printed circuit board and the semiconductor package, and more particularly, to a printed circuit board, a semiconductor package using the same, and a method for manufacturing the printed circuit board and the semiconductor package that can overcome occurrence of a void due to an underfill process after flip-chip interconnection and occurrence of a short between bumps when performing interconnection of a semiconductor chip (flip-chip) and the solder bump.

2. Description of the Related Art

As the high integration of semiconductors has been accelerated, new methods are also required in a packing method. According to this trend, the packaging method is changed from a conventional wire bonding method to a flip-chip bonding method. Even in the flip-chip bonding method, in order to respond to input/output of chips manufactured in 28 nm and below process, a through silicon via (TSV) should be applied. Therefore, new forms of packaging methods are needed.

When applying the flip-chip bonding method, a bonding portion should be filled for high reliability, but as a bump pitch is continuously reduced, a void occurs when applying underfill, thus causing serious defects.

The most basic purpose of solder resist is to secure reliability by protecting circuits inside a PCB. However, in a PCB manufacturing process, many side effects are derived due to the ink or film type solder resist used for this purpose.

That is, in order to cure the solder resist in an uncured state, a high quantity of ultraviolet (UV) rays should take part in curing. Due to this, a solder resist residue exists in an undesired portion (selective open region), thus causing defects such as discoloration and non-plating.

Meanwhile, in a conventional semiconductor packaging manufacturing method, when performing interconnection of a semiconductor chip (flip-chip) 105 and a solder bump 104 as in FIG. la, the volume of the solder bump 104 is changed, and as shown in FIG. 1b, the solder bump 104 spreads to the side. Generally, such volume expansion is not a problem, but when the bump is a fine pitch bump 104′ as shown in FIGS. 2a and 2b, a short between the bumps occurs. In FIGS. 1a to 2b, reference numerals 101, 102, 103, and 105c represent a PCB substrate, a circuit portion, solder resist, and a contact portion, respectively.

### RELATED ART DOCUMENT

### Patent Document

Patent Document 1: Korean Patent Laid-open Publication No. 10-2011-0124562

Patent Document 2: Korean Patent Laid-open Publication No. 10-2011-0110016

### SUMMARY OF THE INVENTION

The present invention has been invented in order to overcome the above-described problems and it is, therefore, an object of the present invention to provide a printed circuit board, a semiconductor package using the same, and a method for manufacturing the printed circuit board and the semiconductor package that can overcome a void due to an underfill process after flip-chip interconnection and a short between bumps when performing interconnection of a semiconductor chip (flip-chip) and the solder bump in a conventional PCB manufacturing method by molding an upper surface portion of a PCB substrate using a preapply underfill material in a B-stage state after forming the solder bump in a PCB manufacturing process.

In accordance with one aspect of the present invention to achieve the object, there is provided a printed circuit board including: a PCB substrate having a circuit of a predetermined pattern on an upper surface; a solder bump formed in the circuit portion to bond a semiconductor chip to the PCB substrate; a second insulating material for molding a certain region of the upper surface portion of the PCB substrate including the solder bump before bonding the semiconductor chip to the PCB substrate; and a first insulating material formed on the PCB substrate to surround the second insulating material and restrict the second insulating material from leaking to the outside.

Here, the second insulating material may be a non-conductive film (NCF) or paste.

Further, the second insulating material may be a B-stage thermosetting resin.

At this time, the thermosetting resin may include an epoxy resin, an amino resin, a phenol resin, a urea resin, a melamine resin, an unsaturated polyester resin, a polyurethane resin, and a polyimide resin.

Further, the first insulating material may be formed in the shape of a continuous barrier or a discontinuous barrier.

At this time, the first insulating material may be solder resist.

In accordance with another aspect of the present invention to achieve the object, there is provided a method for manufacturing a printed circuit board including the steps of: (a) forming a circuit of a predetermined pattern on a PCB substrate; (b) applying a first insulating material on the substrate on which the circuit is formed; (c) removing the first insulating material in the remaining portion except a predetermined portion by exposing and developing the substrate on which the first insulating material is applied; (d) forming a solder bump in the circuit portion exposed by the removal of the first insulating material; and (e) molding a certain region of an upper surface portion of the PCB substrate including the solder bump by filling a second insulating material on the PCB substrate including the circuit portion in which the solder bump is formed.

Here, in the step (b), the first insulating material may be solder resist.

Further, in the step (c), in removing the first insulating material, the first insulating material in a center portion of the substrate on which the circuit of a predetermined pattern is formed may be removed and the first insulating material in an edge portion of the substrate except the center portion may be left.

At this time, the first insulating material in the edge portion of the substrate may be left in the shape of a continuous barrier or a discontinuous barrier.

Further, in the step (e), the second insulating material may be formed in a single layer or a plurality of layers.

Further, in the step (e), the second insulating material may be a non-conductive film (NCF) or paste.

Further, the second insulating material may be a B-stage thermosetting resin.

At this time, the thermosetting resin may include an epoxy resin, an amino resin, a phenol resin, a urea resin, a melamine resin, an unsaturated polyester resin, a polyurethane resin, and a polyimide resin.

In accordance with still another aspect of the present invention to achieve the object, there is provided a semiconductor package including: a PCB substrate having a circuit of a predetermined pattern on an upper surface; a solder bump formed in the circuit portion to bond a semiconductor chip to the PCB substrate; a second insulating material for molding a certain region of the upper surface portion of the PCB substrate including the solder bump before bonding the semiconductor chip to the PCB substrate; a first insulating material formed on the PCB substrate to surround the second insulating material and restrict the second insulating material from leaking to the outside; and a semiconductor chip having a contact portion soldered with the solder bump and integrated with the PCB substrate to form one package by bonding the remaining portion except the contact portion to the second insulating material.

Here, the second insulating material may be a non-conductive film (NCF) or paste.

Further, the second insulating material may be a B-stage thermosetting resin.

At this time, the thermosetting resin may include an epoxy resin, an amino resin, a phenol resin, a urea resin, a melamine resin, an unsaturated polyester resin, a polyurethane resin, and a polyimide resin.

Further, the first insulating material may be formed in the shape of a continuous barrier or a discontinuous barrier.

At this time, the first insulating material may be solder resist.

Further, in accordance with still another aspect of the present invention to achieve the object, there is provided a method for manufacturing a semiconductor package including steps of: (a) forming a circuit of a predetermined pattern on a PCB substrate; (b) applying a first insulating material on the substrate on which the circuit is formed; (c) removing the first insulating material in the remaining portion except a predetermined portion by exposing and developing the substrate on which the first insulating material is applied; (d) forming a solder bump in the circuit portion exposed by the removal of the first insulating material; (e) molding a certain region of an upper surface portion of the PCB substrate including the solder bump by filling a second insulating material on the PCB substrate including the circuit portion in which the solder bump is formed; (f) mounting a semiconductor chip on the PCB substrate so that the contact portion of the semiconductor chip having the contact portion for bonding with the solder bump on one side surface is in contact with the solder bump while facing the solder bump; and (g) completing one package in which the semiconductor chip and the PCB substrate are integrated by applying thermocompression to the semiconductor chip to solder the contact portion by the solder bump and bonding the remaining portion of the semiconductor chip except the contact portion by the second insulating material.

Here, in the step (b), the first insulating material may be solder resist.

Further, in the step (c), in removing the first insulating material, the first insulating material in a center portion of the substrate on which the circuit of a predetermined pattern is formed may be removed and the first insulating material in an edge portion of the substrate except the center portion may be left.

At this time, the first insulating material in the edge portion of the substrate may be left in the shape of a continuous barrier or a discontinuous barrier.

Further, in the step (e), the second insulating material may be formed in a single layer or a plurality of layers.

Further, in the step (e), the second insulating material may be a non-conductive film (NCF) or paste.

Further, the second insulating material may be a B-stage thermosetting resin.

At this time, the thermosetting resin may include an epoxy resin, an amino resin, a phenol resin, a urea resin, a melamine resin, an unsaturated polyester resin, a polyurethane resin, and a polyimide resin.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1a and 1b are views showing a process of bonding a semiconductor chip to a substrate through a solder bump in a process of manufacturing a semiconductor package according to a conventional method;

FIGS. 2a and 2b are views showing the state in which a short is generated between fine-pitch solder bumps during interconnection of the semiconductor chip and the substrate in the process of manufacturing a semiconductor package according to the conventional method;

FIG. 3a is a view showing a structure of a printed circuit board in accordance with an embodiment of the present invention;

FIG. 3b is a view showing a structure of a semiconductor package in accordance with an embodiment of the present invention;

FIG. 4 is a flowchart integrally showing an execution process of a method for manufacturing a printed circuit board and a semiconductor package in accordance with an embodiment of the present invention; and

FIGS. 5a to 5g are views sequentially showing an integrated process of manufacturing a printed circuit board and a semiconductor package according to the method for manufacturing a printed circuit board and a semiconductor package in accordance with the present invention.

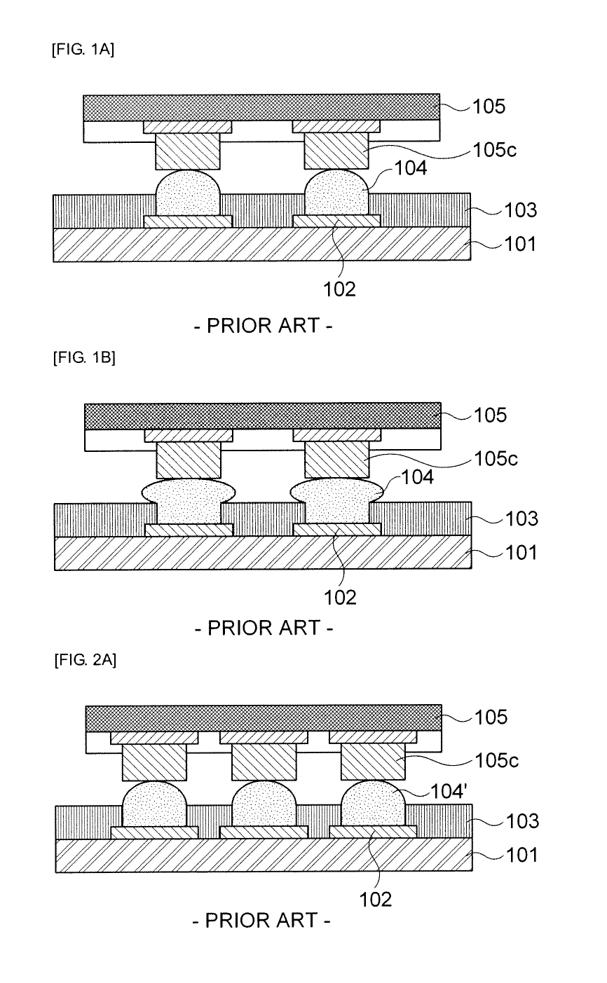

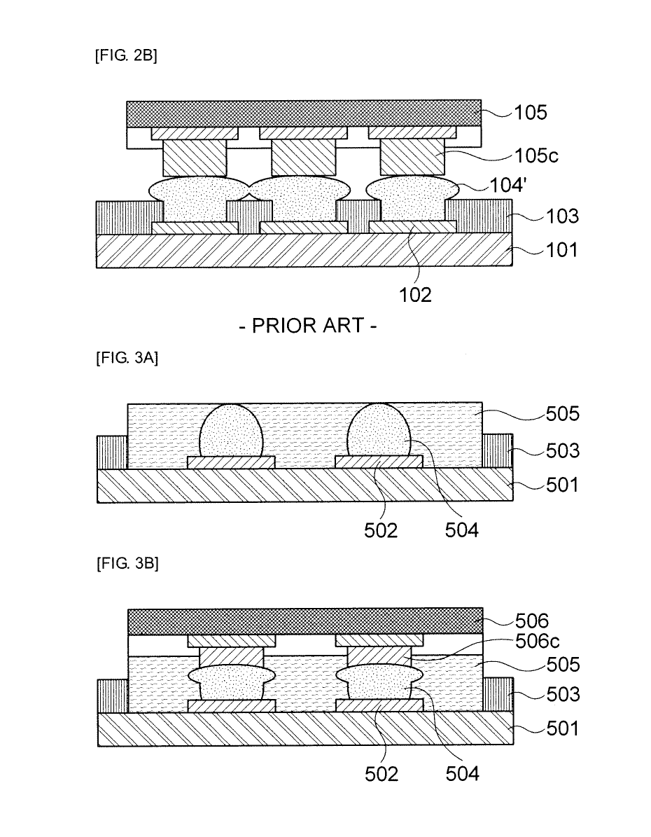

### DETAILED DESCRIPTION OF THE PREFERABLE EMBODIMENTS

The terms or words used in the present specification and claims should not be interpreted as being limited to typical or dictionary meanings, but should be interpreted as having meanings and concepts relevant to the technical spirit of the present invention based on the rule according to which an inventor can appropriately define the concept of the term to describe his/her own invention in the best manner.

Throughout the specification, when an element is referred to as “including” another element, it can further include the other element rather than exclude the other element unless the context clearly indicates otherwise. Further, the terms “unit”, “module”, “apparatus”, etc. used in the present specification represent a unit for processing at least one function or operation and may be implemented by hardware, software, or a combination thereof.

Hereinafter, embodiments of the present invention will be described in detail with reference to the accompanying drawings.

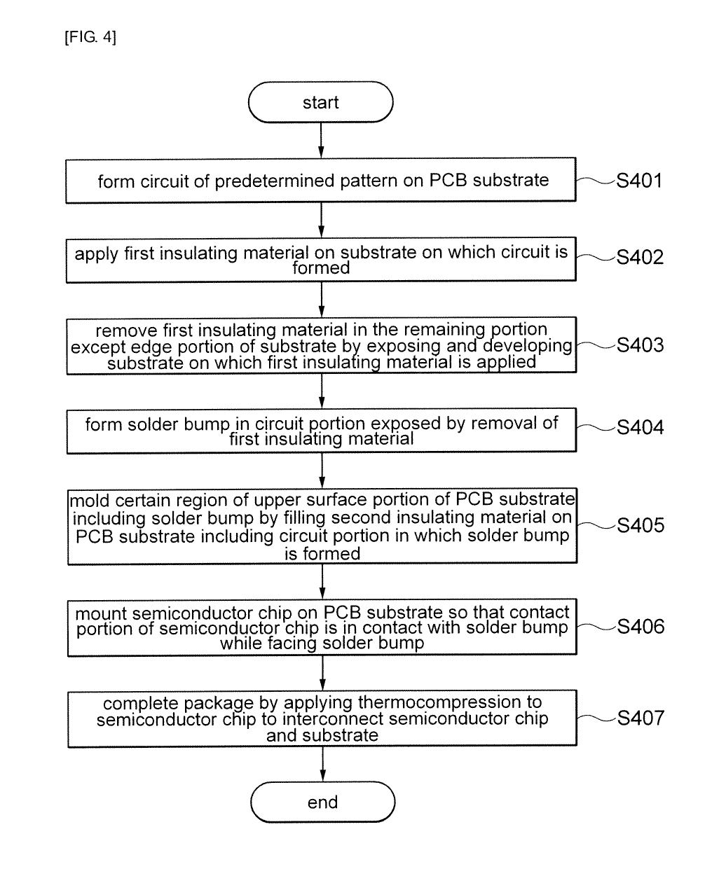

FIGS. 3a and 3b are views respectively showing structures of a printed circuit board and a semiconductor package using the same in accordance with an embodiment of the present invention.

Referring to FIG. 3a, a printed circuit board in accordance with the present invention includes a PCB substrate 501, a solder bump 504, a second insulating material 505, and a first insulating material 503.

The PCB substrate 501 may have a single layer or multilayer internal structure, and a circuit 502 of a predetermined pattern is formed on at least one surface (upper surface in the present embodiment) of the upper and lower surfaces.

The solder bump 504 is formed in the circuit 502 portion to bond a semiconductor chip 506 (refer to FIG. 3b), which will be described later, to the PCB substrate 501.

The second insulating material 505 molds a certain region of the upper surface portion of the PCB substrate 501 including the solder bump 504 before bonding the semiconductor chip 506 to the PCB substrate 501. Here, the second insulating material 505 may be a non-conductive film (NCF) or paste.

Further, the second insulating material 505 may be a B-stage thermosetting resin.

At this time, the thermosetting resin may include an epoxy resin, an amino resin, a phenol resin, a urea resin, a melamine resin, an unsaturated polyester resin, a polyurethane resin, and a polyimide resin.

The first insulating material 503 is formed on the PCB substrate 501 to surround the second insulating material 505, restricts the second insulating material 505 from leaking to the outside, and protects the second insulating material 505 from external impact.

Here, the first insulating material 503 may be formed in the shape of a continuous barrier or a discontinuous barrier. The first insulating material 503 may be solder resist.

Referring to FIG. 3b, it is a semiconductor package using the printed circuit board of FIG. 3a in accordance with an embodiment of the present invention and has a structure in which the semiconductor chip 506 is further added to the printed circuit board of FIG. 3a. Therefore, description of the same components (reference numerals 501 to 505) as the printed circuit board of FIG. 3a will be omitted, and only different components will be described.

As described above, the semiconductor package in accordance with the present invention further includes the semiconductor chip 506 while having the same components (reference numerals 501 to 505) as the printed circuit board of FIG. 3a.

The semiconductor chip 506 has a contact portion 506c soldered with the solder bump 504, and the remaining portion except the contact portion 506c is bonded to the second insulating material 505 and integrated with the PCB substrate 501 to form one package.

All matters related to the first insulating material 503 and the second insulating material 505 in the semiconductor package of the present invention as above are also applied equally to the first insulating material 503 and the second insulating material 505 in the printed circuit board of FIG. 3a.

Then, a method for manufacturing a printed circuit board and a semiconductor package having the above structure in accordance with the present invention will be described.

Here, since the method for manufacturing a semiconductor package in accordance with the present invention has a difference in that it further includes a process of bonding a semiconductor chip to a substrate side later while including the method for manufacturing a printed circuit board in accordance with the present invention as it is, the method for manufacturing a printed circuit board and the method for manufacturing a semiconductor package in accordance with the present invention will be described at the same time.

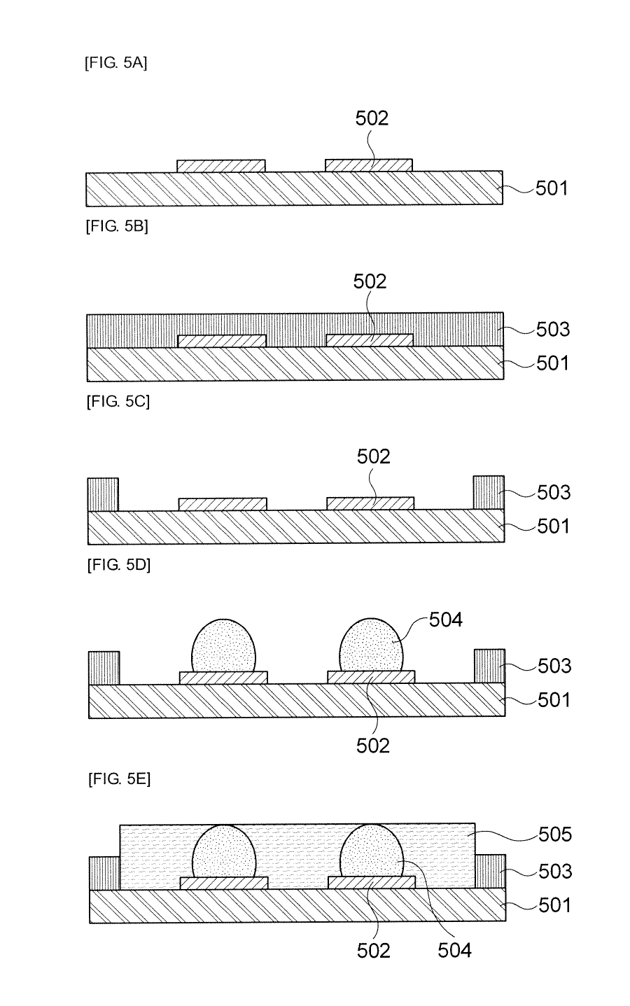

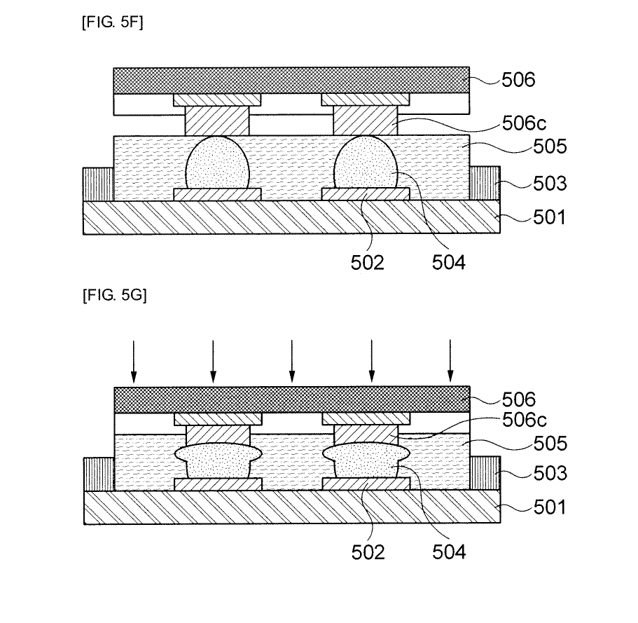

FIG. 4 is a flowchart integrally showing an execution process of the method for manufacturing a printed circuit board and a semiconductor package in accordance with an embodiment of the present invention, and FIGS. 5a to 5g are views sequentially showing an integrated process of manufacturing a printed circuit board and a semiconductor package according to the method for manufacturing a printed circuit board and a semiconductor package in accordance with the present invention.

Referring to FIGS. 4 and 5a to 5g, according to the method for manufacturing a printed circuit board and a semiconductor package, a circuit 502 of a predetermined pattern is formed on a PCB substrate 501 (S401). In order to form the circuit 502 of a predetermined pattern, photolithography using a mask of a predetermined pattern may be used.

After forming the circuit 502, a first insulating material 503 is applied on the substrate 501 on which the circuit 502 is formed (S402). Here, the first insulating material 503 may be solder resist.

When the application of the first insulating material 503 is completed, the first insulating material 503 in the remaining portion except a predetermined portion is removed by exposing and developing the substrate 501 on which the first insulating material 503 is applied (S403). Here, in removing the first insulating material 503, the first insulating material 503 in a center portion of the substrate 501 on which the circuit 502 of a predetermined pattern is formed is removed, and the first insulating material 503 in an edge portion of the substrate 501 except the center portion is left. At this time, the first insulating material 503 in the edge portion of the substrate 501 may be left in the shape of a continuous barrier or a discontinuous barrier. This is to stably fill a second insulating material 505 only in a desired position without leakage to the outside when filling the second insulating material 505 as a preapply underfill material in a subsequent process.

When the removal of the first insulating material 503 in the remaining portion except the edge portion of the substrate 501 is completed by the above step, a solder bump 504 is formed in the circuit 502 portion exposed by the removal of the first insulating material 503 (S404) (refer to FIG. 5d). Here, in order to form the solder bump 504, the solder bump 504 may be formed in the circuit 502 portion as shown in FIG. 5d by performing a photolithography process using a mask of a predetermined pattern after applying, for example, photo resist, on an upper surface region of the substrate 501 exposed by the removal of the first insulating material 503.

When the formation of the solder bump 504 is completed in this way, the second insulating material 505 as a preapply underfill material is filled on the PCB substrate 501 including the circuit 502 portion in which the solder bump 504 is formed to mold a certain region of the upper surface portion of the PCB substrate 501 including the solder bump 504 as in FIG. 5e (S405).

As above, the method of the present invention can overcome occurrence of a void due to an underfill process after flip-chip interconnection and a short between bumps when performing interconnection of a semiconductor chip (flip-chip) and the solder bump in a conventional PCB manufacturing method by molding the upper surface portion of the PCB substrate 501 using the second insulating material 505 as a preapply underfill material after forming the solder bump 504.

Here, further, as in FIG. 5e, although the second insulating material 505 is shown as being filled with the same height as an upper end portion of the solder bump 504, the second insulating material 505 is not necessarily limited to being filled with the same height as the upper end portion of the solder bump 504 like this, and in some cases, the second insulating material 505 may be filled higher or lower than the height of the upper end portion of the solder bump 504.

Further, at this time, the second insulating material 505 may be formed in a single layer or a plurality of layers. This is a case in which a B-stage film type material is used as the second insulating material 505. When the film is attached only one time by a roller (not shown) in a state of 5d, the second insulating material 505 may be formed in a single layer, and when the film is attached several times, the second insulating material 505 may be formed in a plurality of layers. Particularly, when the second insulating material 505 is formed in a plurality of layers, preferably, after previously making the film in a plurality of layers, the film is attached to the PCB substrate 501 of FIG. 5d to make a state like FIG. 5e.

Further, at this time, the second insulating material 505 may be a non-conductive film (NCF) or paste.

Further, the second insulating material 505 may be a B-stage thermosetting resin. When the second insulating material 505 is a B-stage thermosetting resin like this, the B-stage thermosetting resin in a paste state is filled on the PCB substrate 501 including the circuit 502 portion in which the solder bump 504 is formed using an appropriate tool (for example, a tool such as a bar).

At this time, the thermosetting resin may include an epoxy resin, an amino resin, a phenol resin, a urea resin, a melamine resin, an unsaturated polyester resin, a polyurethane resin, and a polyimide resin.

The foregoing is a description of the process of manufacturing a printed circuit board according to the method for manufacturing a printed circuit board in accordance with the present invention.

As described above, the method for manufacturing a semiconductor package in accordance with the present invention includes the method for manufacturing a printed circuit board like the above description as it is while further including a process which will be described later.

That is, after the molding by the filling of the second insulating material 505 in the step

S405 is completed, a semiconductor chip 506 is mounted on the PCB substrate 501 so that a contact portion 506c of the semiconductor chip 506 having the contact portion 506c for bonding with the solder bump 504 on one side surface is in contact with the solder bump 504 while facing the solder bump 504 (S406).

After that, a package is completed by applying thermocompression to the semiconductor chip 506 to interconnect the semiconductor chip 506 and the substrate 501 (S407). At this time, one package in which the semiconductor chip 506 and the PCB substrate 501 is integrated is completed by melting the solder bump 504 through thermocompression to solder the contact portion 506c and bonding the remaining portion of the semiconductor chip 506 except the contact portion 506c through the second insulating material 505.

As in the above description, the method for manufacturing a printed circuit board in accordance with the present invention can overcome occurrence of a void due to an underfill process after flip-chip interconnection and a short between bumps when performing interconnection of a semiconductor chip (flip-chip) and the solder bump in a conventional PCB manufacturing method by molding an upper surface portion of a PCB substrate using a B-stage thermosetting resin as a preapply underfill material after forming the solder bump.

According to the present invention as above, it is possible to overcome a void due to an underfill process after flip-chip interconnection and a short between bumps when performing interconnection of a semiconductor chip (flip-chip) and the solder bump in a conventional PCB manufacturing method by molding an upper surface portion of a PCB substrate using a preapply underfill material in a B-stage state after forming the solder bump.

Although the preferable embodiments of the present invention have been described in detail above, the present invention is not limited to the embodiments and it will be appreciated by those skilled in the art that various modifications and applications may be made in the embodiments without departing from the technical spirit of the present invention. Therefore, the range of protection of the present invention should be interpreted from the appended claims and all technical sprits within the range equivalent to the range should be interpreted as being included in the range of the rights of the present invention.

What is claimed is:

1. A printed circuit board comprising:
a PCB substrate having a circuit of a predetermined pattern on an upper surface;
a solder bump formed in the circuit portion to bond a semiconductor chip to the PCB substrate;
a second insulating material for molding a certain region of the upper surface portion of the PCB substrate including the solder bump before bonding the semiconductor chip to the PCB substrate; and
a first insulating material formed on the PCB substrate to surround the second insulating material and restrict the second insulating material from leaking to the outside.

2. The printed circuit board according to claim 1, wherein the second insulating material is a non-conductive film (NCF) or paste.

3. The printed circuit board according to claim 1, wherein the second insulating material is a B-stage thermosetting resin.

4. The printed circuit board according to claim 3, wherein the thermosetting resin is one of an epoxy resin, an amino resin, a phenol resin, a urea resin, a melamine resin, an unsaturated polyester resin, a polyurethane resin, and a polyimide resin.

5. The printed circuit board according to claim 1, wherein the first insulating material is formed in the shape of a continuous barrier or a discontinuous barrier.

6. The printed circuit board according to claim 1, wherein the first insulating material is solder resist.

7. A method for manufacturing a printed circuit board, comprising:
(a) forming a circuit of a predetermined pattern on a PCB substrate;
(b) applying a first insulating material on the substrate on which the circuit is formed;
(c) removing the first insulating material in the remaining portion except a predetermined portion by exposing and developing the substrate on which the first insulating material is applied;
(d) forming a solder bump in the circuit portion exposed by the removal of the first insulating material; and
(e) molding a certain region of an upper surface portion of the PCB substrate including the solder bump by filling a second insulating material on the PCB substrate including the circuit portion in which the solder bump is formed.

8. The method for manufacturing a printed circuit board according to claim 7, wherein in the step (b), the first insulating material is solder resist.

9. The method for manufacturing a printed circuit board according to claim 7, wherein in the step (c), in removing the first insulating material, the first insulating material in a center portion of the substrate on which the circuit of a predetermined pattern is formed is removed and the first insulating material in an edge portion of the substrate except the center portion is left.

10. The method for manufacturing a printed circuit board according to claim 9, wherein the first insulating material in the edge portion of the substrate is left in the shape of a continuous barrier or a discontinuous barrier.

11. The method for manufacturing a printed circuit board according to claim 7, wherein in the step (e), the second insulating material is formed in a single layer or a plurality of layers.

12. The method for manufacturing a printed circuit board according to claim 7, wherein in the step (e), the second insulating material is a non-conductive film (NCF) or paste.

13. The method for manufacturing a printed circuit board according to claim 7, wherein the second insulating material is a B-stage thermosetting resin.

14. The method for manufacturing a printed circuit board according to claim 13, wherein the thermosetting resin is one of an epoxy resin, an amino resin, a phenol resin, a urea resin, a melamine resin, an unsaturated polyester resin, a polyurethane resin, and a polyimide resin.

15. A semiconductor package comprising:
a PCB substrate having a circuit of a predetermined pattern on an upper surface;
a solder bump formed in the circuit portion to bond a semiconductor chip to the PCB substrate;
a second insulating material for molding a certain region of the upper surface portion of the PCB substrate including the solder bump before bonding the semiconductor chip to the PCB substrate;
a first insulating material formed on the PCB substrate to surround the second insulating material and restrict the second insulating material from leaking to the outside; and
a semiconductor chip having a contact portion soldered with the solder bump and integrated with the PCB substrate to form one package by bonding the remaining portion except the contact portion to the second insulating material.

16. The semiconductor package according to claim 15, wherein the second insulating material is a non-conductive film (NCF) or paste.

17. The semiconductor package according to claim 15, wherein the second insulating material is a B-stage thermosetting resin.

18. The semiconductor package according to claim 17, wherein the thermosetting resin is one of an epoxy resin, an amino resin, a phenol resin, a urea resin, a melamine resin, an unsaturated polyester resin, a polyurethane resin, and a polyimide resin.

19. The semiconductor package according to claim 15, wherein the first insulating material is formed in the shape of a continuous barrier or a discontinuous barrier.

20. The semiconductor package according to claim 15, wherein the first insulating material is solder resist.

21. A method for manufacturing a semiconductor package, comprising:
(a) forming a circuit of a predetermined pattern on a PCB substrate;
(b) applying a first insulating material on the substrate on which the circuit is formed;
(c) removing the first insulating material in the remaining portion except a predetermined portion by exposing and developing the substrate on which the first insulating material is applied;
(d) forming a solder bump in the circuit portion exposed by the removal of the first insulating material;
(e) molding a certain region of an upper surface portion of the PCB substrate including the solder bump by filling a second insulating material on the PCB substrate including the circuit portion in which the solder bump is formed;
(f) mounting a semiconductor chip on the PCB substrate so that a contact portion of the semiconductor chip having the contact portion for bonding with the solder bump on one side surface is in contact with the solder bump while facing the solder bump; and
(g) completing one package in which the semiconductor chip and the PCB substrate are integrated by applying thermocompression to the semiconductor chip to solder the contact portion by the solder bump and bonding the remaining portion of the semiconductor chip except the contact portion by the second insulating material.

22. The method for manufacturing a semiconductor package according to claim 21, wherein in the step (b), the first insulating material is solder resist.

23. The method for manufacturing a semiconductor package according to claim 21, wherein in the step (c), in removing the first insulating material, the first insulating material in a center portion of the substrate on which the circuit of a predetermined pattern is formed is removed and the first insulating material in an edge portion of the substrate except the center portion is left.

24. The method for manufacturing a semiconductor package according to claim 23, wherein the first insulating material in the edge portion of the substrate is left in the shape of a continuous barrier or a discontinuous barrier.

25. The method for manufacturing a semiconductor package according to claim 21, wherein in the step (e), the second insulating material is formed in a single layer or a plurality of layers.

26. The method for manufacturing a semiconductor package according to claim 21, wherein in the step (e), the second insulating material is a non-conductive film (NCF) or paste.

27. The method for manufacturing a semiconductor package according to claim 21, wherein the second insulating material is a B-stage thermosetting resin.

28. The method for manufacturing a semiconductor package according to claim 27, wherein the thermosetting resin is one of an epoxy resin, an amino resin, a phenol resin, a urea resin, a melamine resin, an unsaturated polyester resin, a polyurethane resin, and a polyimide resin.
